(19) United States
(12) Patent Application Publication
(10) Pub. No.: US 2023/0063540 A1
(43) Pub. Date: Mar. 2, 2023

(54) LIGHT DETECTOR, LIGHT DETECTION SYSTEM, LIDAR DEVICE, AND MOBILE BODY

(71) Applicant: KABUSHIKI KAISHA TOSHIBA, Tokyo (JP)

(72) Inventors: Honam KWON, Kawasaki Kanagawa (JP); Mariko SHIMIZU, Setagaya Tokyo (JP); Kazuhiro SUZUKI, Meguro Tokyo (JP)

(73) Assignee: KABUSHIKI KAISHA TOSHIBA, Tokyo (JP)

(21) Appl. No.: 17/680,251

(22) Filed: Feb. 24, 2022

(30) Foreign Application Priority Data
Aug. 25, 2021 (JP) 2021-137088

(51) Int. Cl. H01L 27/146; H01L 31/107; G01S 17/08

(52) U.S. Cl. CPC H01L 27/14627; G01S 17/08; H01L 27/14607; H01L 31/107; G01S 17/89

(57) ABSTRACT

According to one embodiment, a light detector includes a first region, a second region, and a lens group. The first region includes a plurality of elements arranged along a first direction and a second direction. The first direction and the second direction cross each other. Each of the elements includes a first semiconductor region of a first conductivity type, and a second semiconductor region located on the first semiconductor region. The second semiconductor region is of a second conductivity type. The second region is adjacent to the first region in the second direction. The second region has a different structure from the first region. The lens group is positioned on the first and second regions. The lens group includes a plurality of lenses located to correspond respectively to the elements. The first region, the second region, and the lens group are repeatedly provided in the second direction.

### CROSS-REFERENCE TO RELATED APPLICATIONS

This application is based upon and claims the benefit of priority from Japanese Patent Application No.2021-137088, filed on Aug. 25, 2021; the entire contents of which are incorporated herein by reference.

### FIELD

Embodiments described herein relate generally to a light detector, a light detection system, a lidar device, and a mobile body.

### BACKGROUND

There is a light detector that detects light incident on a semiconductor region. It is desirable to increase the light detection efficiency of the light detector.

### BRIEF DESCRIPTION OF THE DRAWINGS

FIG. 1 is a plan view illustrating a light detector according to a first embodiment;

FIG. 2 is an enlarged view of portion II of FIG. 1;

FIG. 3 is a III-III cross-sectional view of FIG. 2;

FIG. 4 is an enlarged view of portion II of FIG. 1;

FIG. 5 is a schematic view showing simulation results relating to the light detector according to the first embodiment;

FIG. 6 is a schematic view showing simulation results relating to a light detector according to a first modification;

FIG. 7 is a schematic view showing simulation results relating to a light detector according to a second modification of the first embodiment;

FIG. 8 is a plan view illustrating a light detector according to a third modification of the first embodiment;

FIG. 9 is an enlarged view of portion IX of FIG. 8;

FIG. 10 is an X-X cross-sectional view of FIG. 9; FIG. 11 is a plan view illustrating a light detector according to a fourth modification of the first embodiment;

FIG. 12 is a XII-XII cross-sectional view of FIG. 11;

FIG. 13 is a cross-sectional view illustrating a light detector according to a fifth modification of the first embodiment;

FIG. 14 is a cross-sectional view illustrating a light detector according to a sixth modification of the first embodiment;

FIG. 15 is a cross-sectional view illustrating a light detector according to a seventh modification of the first embodiment;

FIG. 16 is a cross-sectional view illustrating a light detector according to an eighth modification of the first embodiment;

FIG. 17 is a cross-sectional view illustrating a light detector according to a ninth modification of the first embodiment;

FIG. 18 is a schematic view illustrating a lidar (Laser Imaging Detection and Ranging (LIDAR)) device according to a second embodiment;

FIG. 19 describes the detection of the detection object of the lidar device; and

FIG. 20 is a schematic top view of a mobile body including the lidar device according to the second embodiment.

### DETAILED DESCRIPTION

According to one embodiment, a light detector includes a first region, a second region, and a lens group. The first region includes a plurality of elements arranged along a first direction and a second direction. The first direction and the second direction cross each other. Each of the elements includes a first semiconductor region of a first conductivity type, and a second semiconductor region located on the first semiconductor region. The second semiconductor region is of a second conductivity type. The second region is adjacent to the first region in the second direction. The second region has a different structure from the first region. The lens group is positioned on the first and second regions. The lens group includes a plurality of lenses located to correspond respectively to the elements. The first region, the second region, and the lens group are repeatedly provided in the second direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the following description and drawings, the notations of n⁺, n⁻, p⁺, and p indicate relative levels of the impurity concentrations. In other words, a notation marked with “+” indicates that the impurity concentration is relatively greater than that of a notation not marked with either “+” or “-”; and a notation marked with “-” indicates that the impurity concentration is relatively less than that of a notation without any mark. When both a p-type impurity and an n-type impurity are included in each region, these notations indicate relative levels of the net impurity concentrations after the impurities are compensated.

In embodiments described below, each embodiment may be implemented by inverting the p-type and the n-type of the semiconductor regions.

### First Embodiment

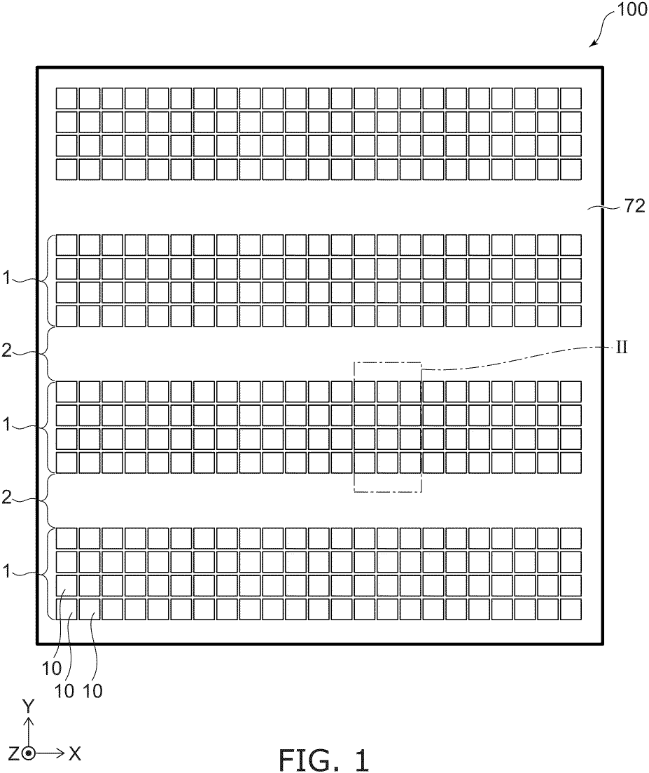

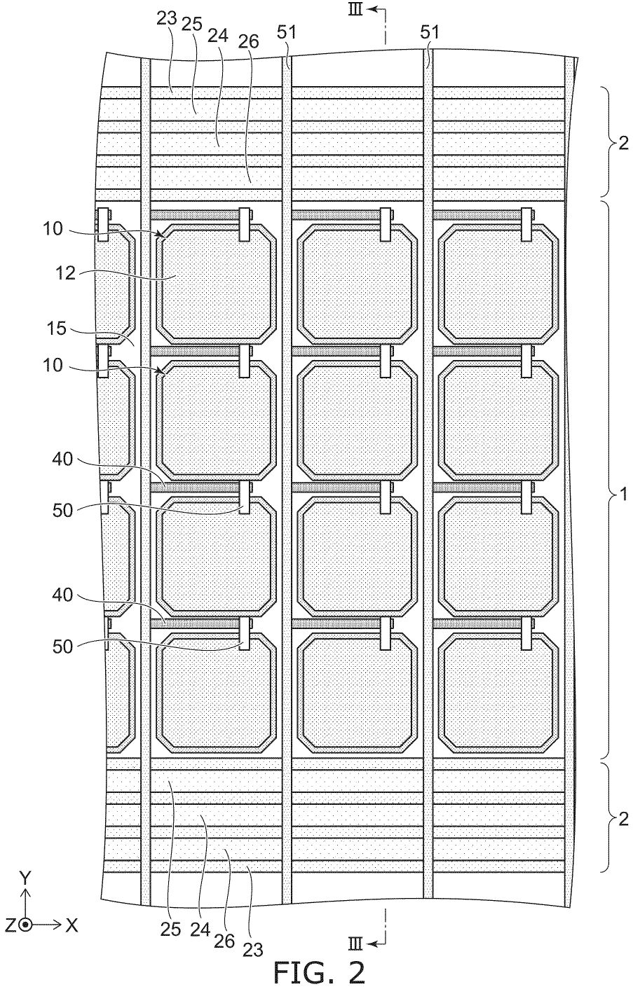

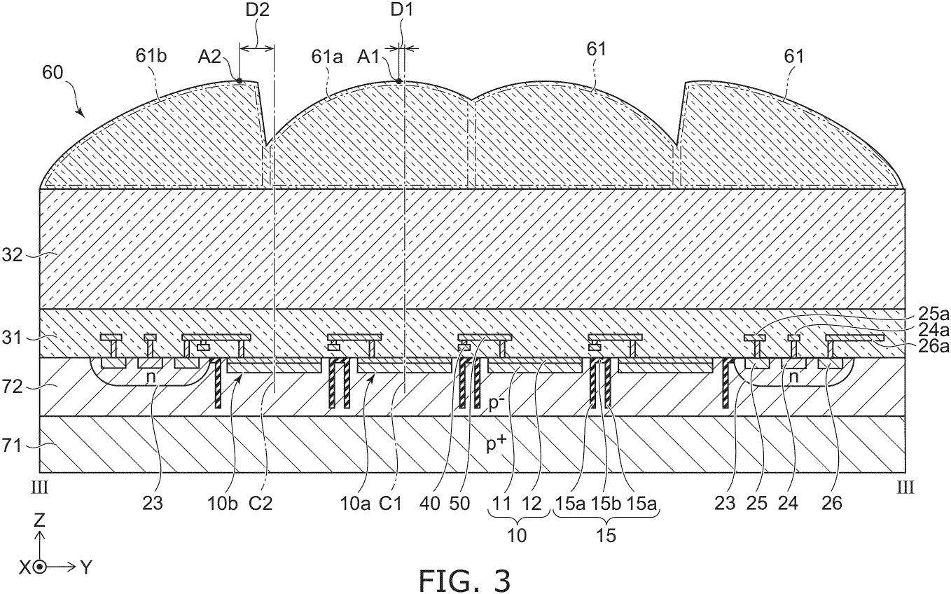

FIG. 1 is a plan view illustrating a light detector according to a first embodiment. FIG. 2 is an enlarged view of portion II of FIG. 1. FIG. 3 is a III-III cross-sectional view of FIG. 2.

As shown in FIGS. 1 to 3, the light detector 100 according to the first embodiment includes a first region 1, a second region 2, an insulating layer 31, an insulating layer 32, a quenching part 40, an interconnect 50, a common line 51, a lens group 60, a p⁺-type semiconductor layer 71 (a first semiconductor layer), and a p⁻-type semiconductor layer 72 (a second semiconductor layer). FIG. 1 shows only the first region 1, the second region 2, and the p⁻-type semiconductor layer 72. The lens group 60, the insulating layer 32, the insulating layer 31, and the interconnects located in the second region 2 are not illustrated in FIG. 2.

As shown in FIG. 1, multiple elements 10 are located in the first region 1. The multiple elements 10 are arranged along two directions that cross each other. Here, one of the arrangement directions is taken as an X-direction (a first direction). Another arrangement direction that crosses the X-direction is taken as a Y-direction (a second direction). In the example of FIG. 1, the X-direction and the Y-direction are mutually-orthogonal.

The second region 2 has a different structure from the first region 1, and is adjacent to the first region 1. The first region 1 and the second region 2 are repeatedly provided in the Y-direction. For example, one second region 2 is located between two mutually-adjacent first regions 1. One first region 1 is located between two mutually-adjacent second regions 2.

The first region 1 functions as a cell region in which the element 10 for detecting light is located. The second region 2 does not include the element 10. The second region 2 functions as a peripheral region in which components of the light detector 100 other than the element 10 are located.

As shown in FIG. 3, each element 10 includes a p-type (first-conductivity-type) semiconductor region 11 (a first semiconductor region) and an n⁺-type (second-conductivity-type) semiconductor region 12 (a second semiconductor region). The direction from the p-type semiconductor region 11 toward the n⁺-type semiconductor region 12 is taken as a Z-direction. The Z-direction is perpendicular to the X-Y plane. In the description, the direction from the p-type semiconductor region 11 toward the n⁺-type semiconductor region 12 is called “up”, and the opposite direction is called “down”. These directions are based on the relative positional relationship between the p-type semiconductor region 11 and the n⁺-type semiconductor region 12 and are independent of the direction of gravity.

The first region 1 and the second region 2 are located on the p⁻-type semiconductor layer 72. The p⁻-type semiconductor layer 72 is located on the p⁺-type semiconductor layer 71. The n⁺-type semiconductor region 12 is located on the p-type semiconductor region 11. A p-n junction surface is formed between the p-type semiconductor region 11 and the n⁺-type semiconductor region 12. For example, the p-n junction surface is parallel to the X-Y plane. The n-type impurity concentration in the n⁺-type semiconductor region 12 is greater than the p-type impurity concentration in the p-type semiconductor region 11. The p-type impurity concentration in the p-type semiconductor region 11 is greater than the p-type impurity concentration in the p⁻-type semiconductor layer 72. The p-type impurity concentration in the p⁻-type semiconductor layer 72 is less than the p-type impurity concentration in the p⁺-type semiconductor layer 71. The p-type semiconductor region 11 is electrically connected to the p⁺-type semiconductor layer 71 via the p⁻-type semiconductor layer 72.

The first region 1 further includes an insulating part 15. The insulating part 15 is located around the elements 10 in the X-direction and the Y-direction. For example, the insulating part 15 includes multiple first insulating regions 15a and a second insulating region 15b. The multiple first insulating regions 15a are located respectively around the multiple elements 10. The lower end of the first insulating region 15a is positioned lower than the p-type semiconductor region 11. The first insulating region 15a may contact the p⁺-type semiconductor layer 71. The second insulating region 15b is located on the multiple first insulating regions 15a and is positioned around the n⁺-type semiconductor regions 12. By providing the insulating part 15, the secondary photons that are generated in the element 10 can be prevented from being incident on the adjacent elements 10.

As shown in FIG. 3, the n⁺-type semiconductor region 12 is electrically connected to the common line 51 via the quenching part 40. Specifically, the quenching part 40 is electrically connected to the n⁺-type semiconductor region 12 via the interconnect 50 and a contact plug. The common line 51 is electrically connected to the quenching part 40 via a contact plug. One common line 51 extends in the Y-direction and is electrically connected to multiple n⁺-type semiconductor regions 12 arranged in the Y-direction.

The second region 2 includes an n-type semiconductor region 23 (a third semiconductor region), a p⁺-type semiconductor region 24 (a fourth semiconductor region), an n⁺-type semiconductor region 25, and an n⁺-type semiconductor region 26. The p⁺-type semiconductor region 24, the n⁺-type semiconductor region 25, and the n⁺-type semiconductor region 26 are located on the n-type semiconductor region 23 and arranged along the Y-direction. The n-type impurity concentration in the n-type semiconductor region 23 is greater than the p-type impurity concentration in the p⁻-type semiconductor layer 72. The p-type impurity concentration in the p⁺-type semiconductor region 24, the n-type impurity concentration in the n⁺-type semiconductor region 25, and the n-type impurity concentration in the n⁺-type semiconductor region 26 each are greater than the n-type impurity concentration in the n-type semiconductor region 23.

A reverse voltage is applied between the p⁻-type semiconductor layer 72 and the n-type semiconductor region 23. A depletion layer that spreads from the interface between the p⁻-type semiconductor layer 72 and the n-type semiconductor region 23 does not reach the p⁺-type semiconductor region 24, the n⁺-type semiconductor region 25, or the n⁺-type semiconductor region 26. Thereby, the p⁺-type semiconductor region 24, the n⁺-type semiconductor region 25, and the n⁺-type semiconductor region 26 are electrically isolated from the p⁻-type semiconductor layer 72.

Circuit elements are located in the second region 2. In other words, in the light detector 100, the second region 2 functions as a circuit region in which circuit elements are provided. The circuit elements include passive elements such as capacitors, resistances and the like, active elements such as diodes, transistors, etc. For example, the p⁺-type semiconductor region 24, the n⁺-type semiconductor region 25, and the n⁺-type semiconductor region 26 each are included in a portion of a circuit element.

The p⁺-type semiconductor region 24 is electrically connected to an interconnect 24a via a contact plug. The n⁺-type semiconductor region 25 is electrically connected to an interconnect 25a via a contact plug. The n⁺-type semiconductor region 26 is electrically connected to an interconnect 26a via a contact plug. At least one of the interconnects 24a to 26a may be electrically connected to the common line 51.

The insulating layer 31 is light-transmissive and is located on the multiple first regions 1 and the multiple second regions 2. The interconnects 24a to 26a, the quenching part 40, the interconnect 50, the common line 51, etc., are located in the insulating layer 31. The insulating layer 32 is light-transmissive and is located on the insulating layer 31 for planarization.

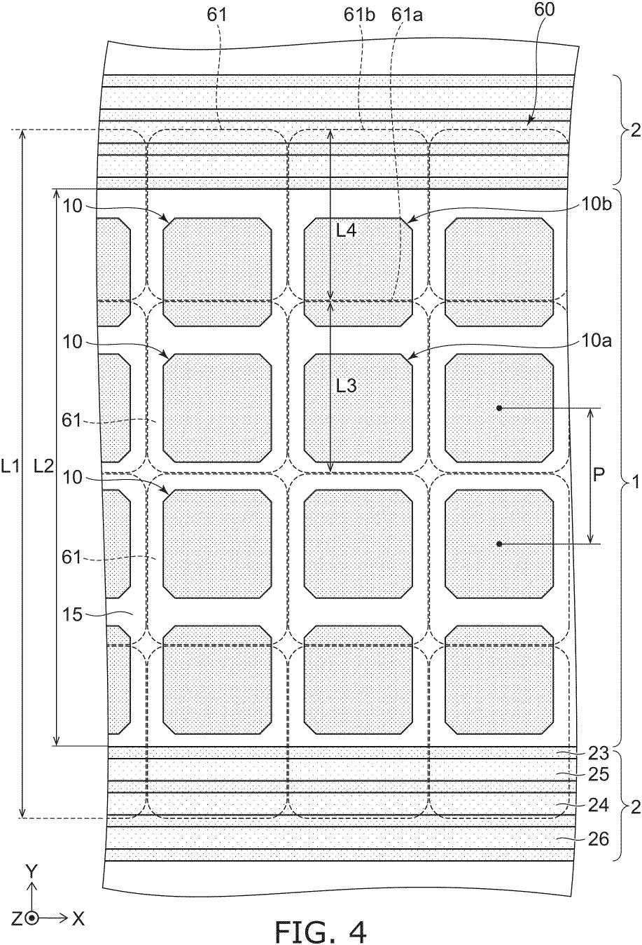

FIG. 4 is an enlarged view of portion II of FIG. 1. FIG. 4 shows only the element 10, the insulating part 15, the semiconductor regions of the second region 2, and the lens group 60.

As shown in FIGS. 3 and 4, the lens group 60 is located on the insulating layer 32. The multiple lens groups 60 are located to correspond respectively to the multiple first regions 1. The lens group 60 includes multiple lenses 61 that are light-transmissive. The multiple lenses 61 that are included in one lens group 60 are located to correspond respectively to the multiple elements 10 included in one first region 1.

The shape of the upper surface of the lens 61 is convex upward. The lens 61 is a plano-convex lens that concentrates light on the element 10. For example, the shape of the multiple lenses 61 included in the lens group 60 is symmetric in the Y-direction. Specifically, the shape of the multiple lenses 61 has planar symmetry with respect to an X-Z plane passing through the center in the Y-direction of the lens group 60. The shape of each lens 61 is asymmetric in the Y-direction.

As shown in FIG. 4, a length L1 in the Y-direction of the lens group 60 is greater than a length L2 in the Y-direction of the first region 1. Therefore, the lens group 60 is positioned on the first and second regions 1 and 2. The shape of the lens 61 is substantially a quadrilateral, a rounded quadrilateral, an ellipse, or a circle when viewed along the Z-direction.

For example, as shown in FIGS. 3 and 4, the multiple elements 10 include a first element 10a and a second element 10b. The multiple lenses 61 include a first lens 61a and a second lens 61b. The first lens 61a is located to correspond to the first element 10a. The second lens 61b is located to correspond to the second element 10b. The first element 10a and the second element 10b are adjacent to each other in the Y-direction. The second element 10b is positioned between the first element 10a and the second region 2 in the Y-direction. The first lens 61a and the second lens 61b are adjacent to each other in the Y-direction.

A portion of the first lens 61a is positioned on the first element 10a. Another portion of the first lens 61a is positioned on the second element 10b. A portion of the second lens 61b is positioned on the second element 10b. Another portion of the second lens 61b is positioned on the second region 2.

The shift amount in the Y-direction of the lens 61 with respect to the corresponding element 10 increases as the lens 61 is positioned further toward the outer perimeter of the lens group 60. For example, as shown in FIG. 3, in the Y-direction, a distance D2 between a center C2 of the second element 10b and an apex A2 of the second lens 61b is greater than a distance D1 between a center C1 of the first element 10a and an apex A1 of the first lens 61a. The center C1 is a center in the X-Y plane of the first element 10a. The center C2 is a center in the X-Y plane of the second element 10b.

More specifically, the apex A1 of the first lens 61a is positioned outward the center C1 of the first element 10a. The apex A2 of the second lens 61b is positioned outward the center C2 of the second element 10b. The second lens 61b does not exist inward of the center of the second element 10b. “Outward” is the direction from the first region 1 to the second region 2. “Inward” is the direction from the second region 2 to the first region 1. According to this configuration, the light that has passed through the second lens 61b is incident on the second element 10b along an oblique direction inclined with respect to the Z direction. The light is refracted toward the center of the second element 10b due to the difference in refractive index between the insulating layer 31 and the semiconductor region. The outer periphery of the element 10 may be a dead region where avalanche breakdown does not occur even when light is incident. As the amount of light traveling toward the center of the element 10 increases, the incident light on the light detector 100 can be easily detected as a signal. That is, the light-receiving sensitivity of the light detector 100 can be improved.

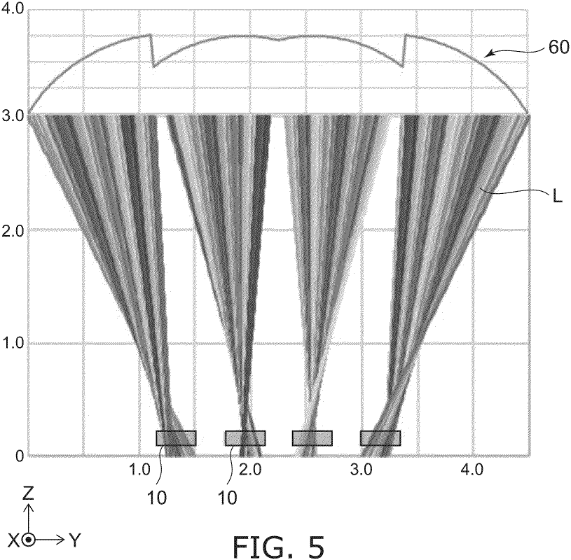

FIG. 5 is a schematic view showing simulation results relating to the light detector according to the first embodiment.

FIG. 5 shows simulation results of ray tracing relating to the light detector 100. The normalized positional relationship of the components is shown at the bottom and left in FIG. 5. As shown in FIG. 5, the shape of the upper surface of each lens 61 is adjusted to concentrate light L on the corresponding element 10. From the simulation results of FIG. 5, it can be seen that the light L from the lenses 61 positioned on the second region 2 is concentrated on the corresponding elements 10.

### Operations of the Light Detector 100 Will Now Be Described

A reverse voltage is applied between the p-type semiconductor region 11 and the n⁺-type semiconductor region 12. For example, the element 10 functions as a P-I-N diode or an avalanche photodiode. It is favorable for the element 10 to function as an avalanche photodiode.

A charge is generated by the element 10 when light is incident on the element 10 from above. The charge flows toward the common line 51 via the n⁺-type semiconductor region 12 and the quenching part 40. An output current that corresponds to the incident light of the element 10 can be detected by detecting the current flowing in the common line 51.

A reverse voltage that is greater than the breakdown voltage may be applied between the p-type semiconductor region 11 and the n⁺-type semiconductor region 12. In other words, the element 10 may operate in a Geiger mode. By operating in the Geiger mode, a pulse signal that has a high multiplication factor (i.e., a high gain) is output. The light-receiving sensitivity of the light detector 100 can be increased thereby. The element 10 may function as a single photon avalanche diode for detecting faint light.

The quenching part 40 is provided to suppress the continuation of avalanche breakdown when avalanche breakdown occurs due to the incidence of light on the element 10. The electrical resistance of the quenching part 40 is greater than the electrical resistances of the contact plugs, the interconnect 50, the common line 51, etc. It is favorable for the electrical resistance of the quenching part 40 to be not less than 50 kΩ and not more than 6 MΩ. A voltage drop that corresponds to the electrical resistance of the quenching part 40 occurs when avalanche breakdown occurs and a current flows in the quenching part 40. The potential difference between the p-type semiconductor region 11 and the n⁺-type semiconductor region 12 is reduced by the voltage drop, and the avalanche breakdown stops. Thereby, the element 10 has a fast response with a short time constant; and the next light that is incident on the element 10 can be detected again.

### An Example of Materials of the Components Will Now Be Described

The p-type semiconductor region 11, the n⁺-type semiconductor region 12, the n-type semiconductor region 23, the p⁺-type semiconductor region 24, the n⁺-type semiconductor region 25, the n⁺-type semiconductor region 26, the p⁺-type semiconductor layer 71, and the p⁻-type semiconductor layer 72 include at least one semiconductor material selected from the group consisting of silicon, silicon carbide, gallium arsenide, and gallium nitride. For example, phosphorus, arsenic, or antimony is used as the n-type impurity when these semiconductor regions include silicon. Boron or boron fluoride is used as the p-type impurity.

The insulating part 15, the insulating layer 31, and the insulating layer 32 include insulating materials. For example, the insulating part 15, the insulating layer 31, and the insulating layer 32 include silicon oxide or silicon nitride. The quenching part 40 includes polysilicon. An n-type impurity or a p-type impurity may be added to the quenching part 40. The contact plugs and the interconnects include metal materials such as tungsten, titanium, copper, aluminum, etc.

The lens 61 includes a light-transmissive resin. It is favorable for the resin to be an acrylic resin. The acrylic resin may be a resin into which propylene glycol monomethyl ether acetate is mixed. The shape of each lens 61 can be adjusted by controlling the exposure amount at each portion in the X-Y plane in the photolithography process.

### Advantages of the First Embodiment Will Now be Described

To increase the light detection efficiency of the light detector 100, it is favorable for the light that enters the light detector 100 to be easily incident on the element 10. On the other hand, other than the first region 1 that includes the element 10, the second region 2 also is included in the light detector 100. Circuit elements, etc., are located in the second region 2; and the element 10 is not located in the second region 2. Therefore, the light that enters the light detector 100 is not detected in the second region 2. To increase the light detection efficiency, it is favorable for the light that enters toward the second region 2 also to be detected.

The lens group 60 is included in the light detector 100. The lens group 60 is located on the first and second regions 1 and 2. Therefore, the light that enters toward the second region 2 can be refracted toward the first region 1. According to the first embodiment, light that is incident on the light detector 100 in a wider area can be detected by the element 10; and the light detection efficiency of the light detector 100 can be increased.

It is favorable for the length L1 in the Y-direction of the lens group 60 to be greater than the length L2 in the Y-direction of the first region 1. By setting the length L1 to be greater than the length L2, the light that is in a wider area can be refracted toward the first region 1. The light detection efficiency of the light detector 100 can be further improved.

The multiple lenses 61 that are included in the lens group 60 may be separated from each other or may be linked to each other. However, to increase the light detector efficiency, it is favorable to increase the surface area of the upper surface of each lens 61. To increase the surface area, it is favorable for the multiple lenses 61 to be linked to each other. The multiple lens groups 60 may be linked to each other.

In the light detector 100, the distance between the lens 61 and the corresponding element 10 increases as the lens 61 is positioned further toward the outer perimeter. Therefore, the light that is refracted by the lens 61 positioned at the outer perimeter is easily scattered or absorbed before being incident on the corresponding element 10. It is favorable for the light detection efficiency difference to be small between the element 10 positioned at the center of the first region 1 and the element 10 positioned at the outer perimeter. To reduce the detection efficiency difference, it is favorable for the Y-direction length to increase as the lens 61 is positioned further toward the outer perimeter of the lens group 60. For example, as shown in FIG. 4, a length L4 in the Y-direction of the second lens 61b is greater than a length L3 in the Y-direction of the first lens 61a. In other words, the surface area increases as the lens 61 is positioned further toward the outer perimeter of the lens group 60.

As shown in FIG. 4, the multiple elements 10 that are included in the first region 1 are arranged at a pitch P in the Y-direction. It is favorable for the surface area of the multiple lenses 61 included in one lens group 60 to be greater than 1.05 times and less than 4 times the square of the pitch P. When the surface area is less than 1.05 times the square of the pitch P, it is difficult to obtain the light detection efficiency improvement effects. On the other hand, when the surface area is greater than 4 times the square of the pitch P, the distance between the lens 61 positioned at the outer perimeter and the corresponding element 10 becomes too long. It may be difficult to pattern the upper surface shape to increase the refraction angle of the light due to the lens 61.

### First Modification

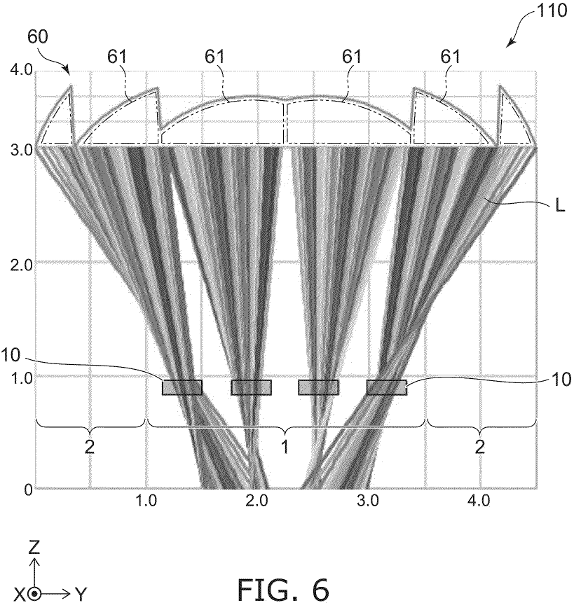

FIG. 6 is a schematic view showing simulation results relating to a light detector according to a first modification.

As shown in FIG. 6, the structure of the lens group 60 of the light detector 110 according to the first modification is different from that of the light detector 100. In the light detector 100, one lens 61 is provided for one element 10. In the light detector 110, multiple lenses 61 are provided for each element 10 positioned at the outer perimeter of the first region 1. The shapes of the upper surfaces of the multiple lenses 61 provided for one element 10 are different from each other.

According to the first modification, compared to the light detector 100, the refraction angle due to the lens 61 positioned at the outer perimeter of the lens group 60 can be increased. Thereby, the distance in the Z-direction between the element 10 and the lens 61 can be short. For example, the absorption or the scattering of the light by the insulating layers 31 and 32 can be suppressed, and the size in the Z-direction of the light detector 110 can be reduced.

Similarly to FIG. 5, FIG. 6 shows simulation results of the ray tracing. From FIG. 6, it can be seen that the light L that is refracted by each lens 61 is incident on the corresponding element 10. Thus, the specific shape of the upper surface of each lens 61 is arbitrary as long as the lens 61 can concentrate light on the corresponding element 10.

### Second Modification

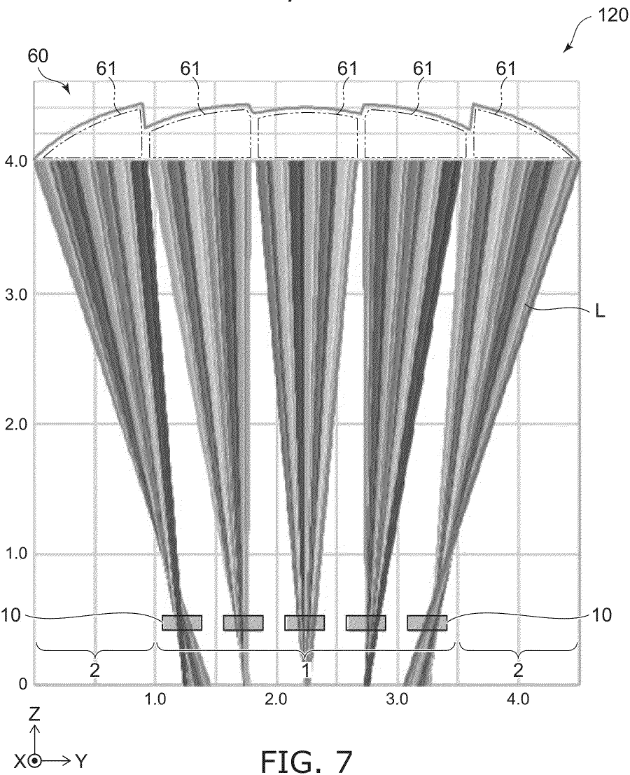

FIG. 7 is a schematic view showing simulation results relating to a light detector according to a second modification of the first embodiment.

As shown in FIG. 7, the number of the elements 10 arranged in one first region 1 of the light detector 120 according to the second modification is different from that of the light detector 100. In the light detector 120, five elements 10 are arranged in one first region 1 in the Y-direction.

Similarly to FIG. 5, FIG. 7 shows simulation results of the ray tracing. From FIG. 7, it can be seen that the light L that is refracted by each lens 61 is incident on the corresponding element 10. Thus, the number of the elements 10 located in one first region 1 is arbitrary. Also, the Y-direction length of one second region 2 is modifiable as appropriate according to the structure of one first region 1.

When an odd number of elements 10 is arranged in the Y-direction in one first region 1, the shape of the lens 61 corresponding to the element 10 at the center may be symmetric in the Y-direction. For example, the center in the Y-direction of the element 10 at the center and the apex of the corresponding lens 61 are arranged in the Z-direction. The shape of the corresponding lens 61 has planar symmetry with respect to the X-Z plane passing through the center in the Y-direction of the lens 61.

In the simulations shown in FIGS. 5 to 7, a spherical lens is used as the lens 61. The lens 61 may be an aspherical lens. By using an aspherical lens, the light-collecting property to the element 10 can be further improved.

### Third Modification

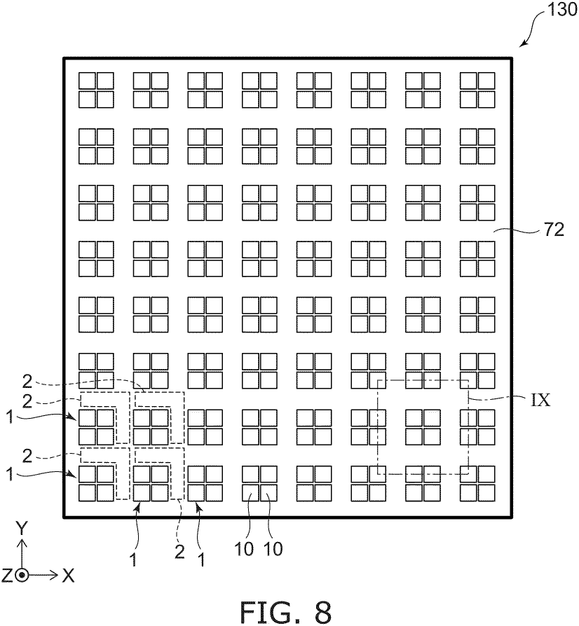

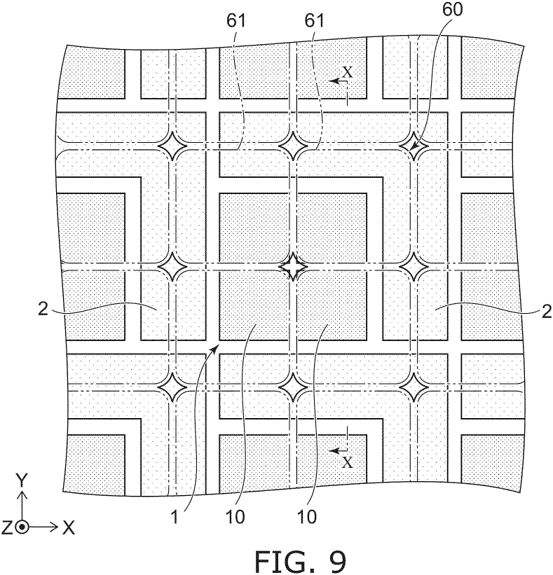

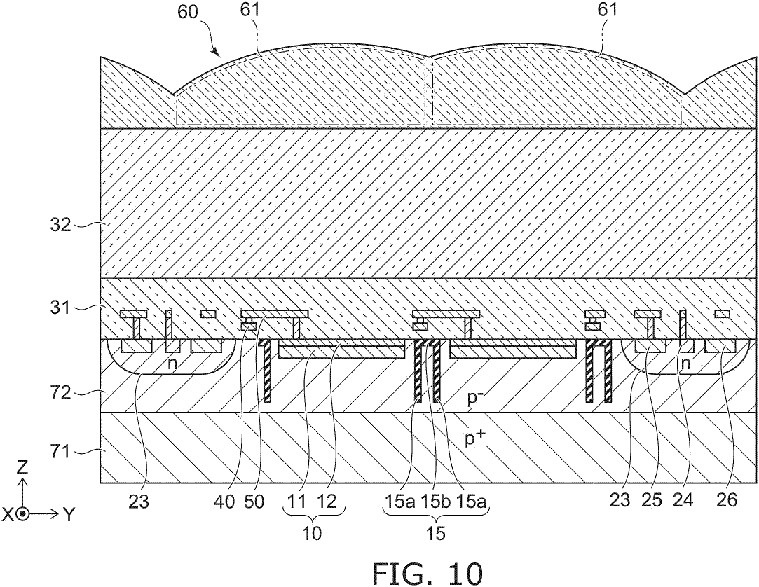

FIG. 8 is a plan view illustrating a light detector according to a third modification of the first embodiment. FIG. 9 is an enlarged view of portion IX of FIG. 8. FIG. 10 is an X-X cross-sectional view of FIG. 9. FIG. 8 shows only the first region 1, the second region 2, and the p⁻-type semiconductor layer 72. FIG. 9 shows only the first region 1, the second region 2, and the lens group 60.

In the light detector 130 according to the third modification as shown in FIG. 8, the first region 1 and the second region 2 are repeatedly provided in the X-direction and the Y-direction. Accordingly, the lens group 60 also is repeatedly provided in the X-direction and the Y-direction.

As shown in FIG. 9, the Y-direction length of one lens group 60 is greater than the Y-direction length of the first region 1. The length in the X-direction of one lens group 60 is greater than the length in the X-direction of the first region 1. In the light detector 130 as shown in FIGS. 9 and 10, the lens groups 60 are linked to each other. Thereby, the surface area of each lens 61 can be increased.

One lens group 60 that corresponds to one first region 1 is discriminated by determining the multiple lenses 61 that refract the light toward the one first region 1.

For example, as shown in FIG. 10, the shape of the lens group 60 is symmetric in the Y-direction. The shape of each lens 61 is asymmetric in the Y-direction. Similarly, the shape of the lens group 60 is symmetric in the X-direction. Specifically, the shape of the multiple lenses 61 has planar symmetry with respect to the Y-Z plane passing through the center in the X-direction of the lens group 60. The shape of each lens 61 is asymmetric in the X-direction.

### Fourth Modification

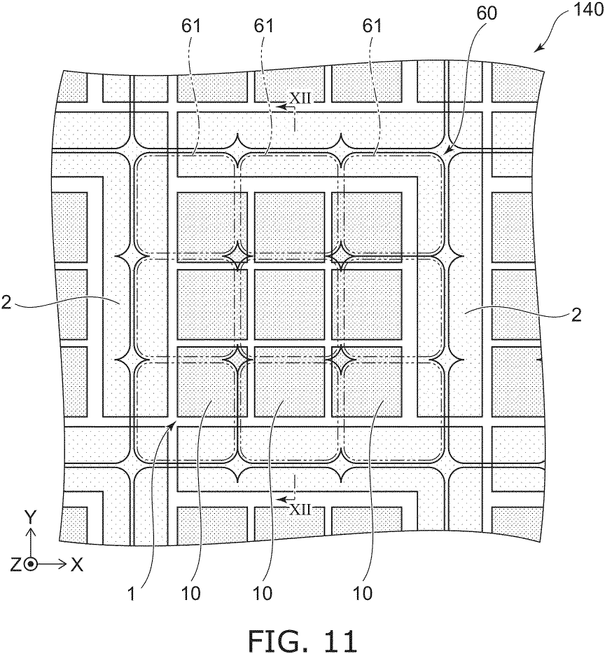

FIG. 11 is a plan view illustrating a light detector according to a fourth modification of the first embodiment. FIG. 12 is a XII-XII cross-sectional view of FIG. 11. FIG. 11 shows only the first region 1, the second region 2, and the lens group 60.

In the light detector 130, two elements 10 are provided in each of the X-direction and the Y-direction in one first region 1. In the light detector 140 according to the fourth modification as shown in FIG. 11, three elements 10 are provided in each of the X-direction and the Y-direction in one first region 1.

In the light detector 140 as shown in FIG. 12, the shape of the lens group 60 is symmetric in the Y-direction. The shape of the lens 61 positioned at the Y-direction center of one lens group 60 is symmetric in the Y-direction. The shapes of the other lenses 61 are asymmetric in the Y-direction. This is similar in the X-direction.

For example, in the light detector 140 as well, similarly to the light detector 100, a portion of the first lens 61a is positioned on the first element 10a. Another portion of the first lens 61a is positioned on the second element 10b. A portion of the second lens 61b is positioned on the second element 10b. Another portion of the second lens 61b is positioned on the second region 2. In the Y-direction, the distance between the center C2 of the second element 10b and the apex A2 of the second lens 61b is greater than the distance D1 between the center C1 of the first element 10a and the apex A2 of the first lens 61a.

As in the third and fourth modifications, the first region 1, the second region 2, and the lens group 60 may be repeatedly provided in two directions that cross each other.

### Fifth Modification

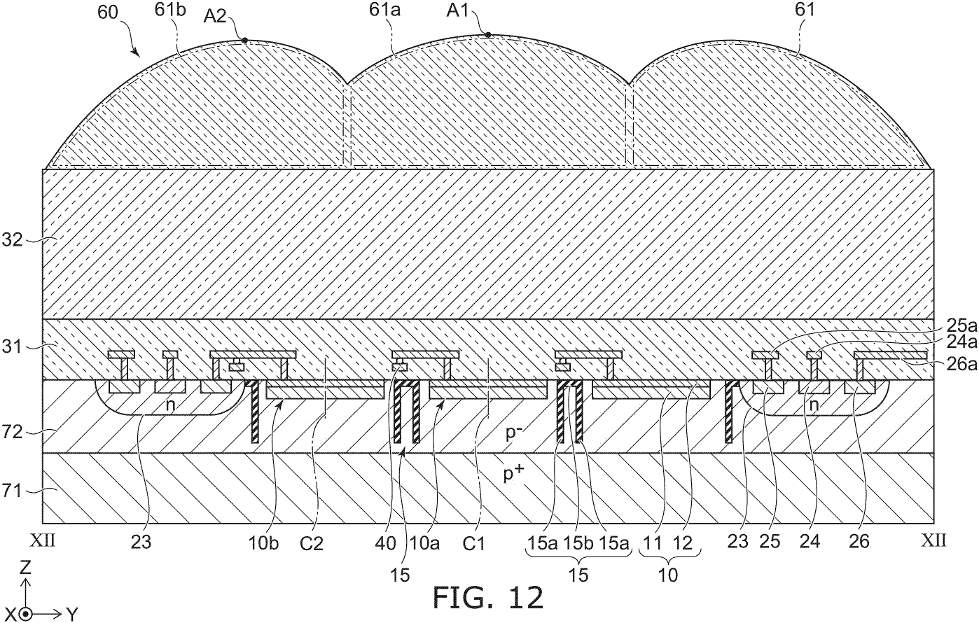

FIG. 13 is a cross-sectional view illustrating a light detector according to a fifth modification of the first embodiment.

In the light detector 100, as shown in FIGS. 3 and 4, the apex of the lens 61 is deviated from the center of the element 10 on the X-Y plane. In a light detector 150 shown in FIG. 13, the apex of the lens 61 is aligned with the center of the element 10 on the X-Y plane in the Z direction. Therefore, in the light detector 150, the distance D1 and the distance D2 shown in FIG. 3 are zero. For example, when viewed in the Z direction, the apex A1 of the first lens 61a overlaps the center C1 of the first element 10a. When viewed in the Z direction, the apex A2 of the second lens 61b overlaps the center C2 of the second element 10b.

When the apex of the lens 61 and the center of the element 10 are aligned in the Z direction, the amount of light traveling toward the center of the element 10 can be increased, and the amount of light traveling toward the outer periphery of the element 10 can be decreased. The outer periphery of the element 10 may be a dead region where avalanche breakdown does not occur even when light is incident. By increasing the amount of light traveling toward the center of the element 10, the light-receiving sensitivity of the light detector 150 can be improved.

### Sixth Modification

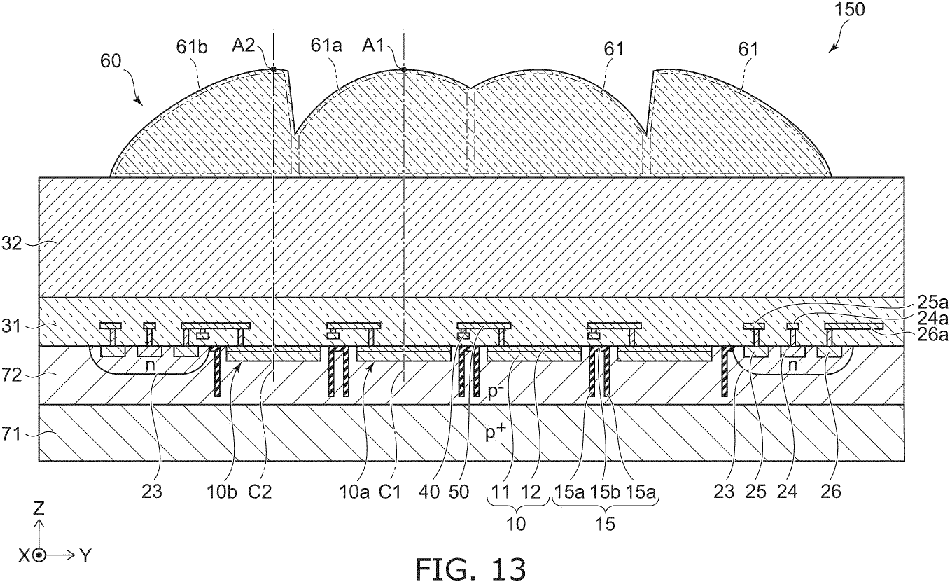

FIG. 14 is a cross-sectional view illustrating a light detector according to a sixth modification of the first embodiment.

In the light detectors 100 to 150, a resistor that generates a large voltage drop is included as the quenching part 40. Conversely, in the light detector according to the sixth modification, a control circuit and a switching element are included as the quenching part. In other words, an active quenching circuit for blocking the current is included as the quenching part 40.

As shown in FIG. 14, the light detector 160 according to the sixth modification includes a control circuit CC and a switching array SWA. The control circuit CC includes a comparator, a control logic part, etc. The switching array SWA includes multiple switching elements SW. For example, at least a portion of the circuit elements included in the control circuit CC and the switching elements SW is formed in the second region 2.

One switching element SW may be provided for one element 10 as shown in FIG. 14, or one switching element SW may be provided for multiple elements 10. For example, the switching element SW may be located between the common line 51 and the n⁺-type semiconductor regions 12, or the switching elements SW may be located in the common line 51.

### Seventh Modification

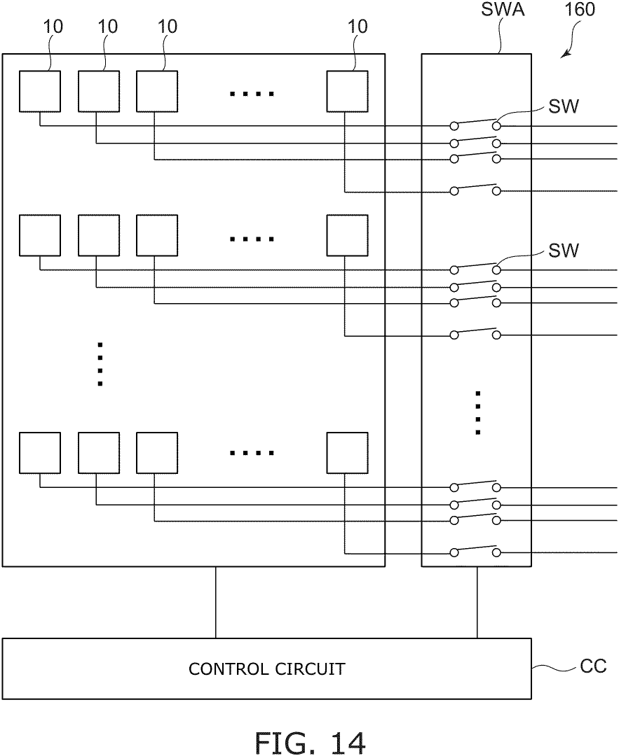

FIG. 15 is a cross-sectional view illustrating a light detector according to a seventh modification of the first embodiment.

In the light detector 170 according to the seventh modification as shown in FIG. 15, the second region 2 includes a metal member 80 and an insulating layer 81 instead of the n-type semiconductor region 23, the p⁺-type semiconductor region 24, the n⁺-type semiconductor region 25, and the n⁺-type semiconductor region 26.

The metal member 80 extends in the Z-direction and is surrounded with the p⁺-type semiconductor layer 71 and the p⁻-type semiconductor layer 72. The insulating layer 81 is located between the p⁺-type semiconductor layer 71 and the metal member 80 and between the p⁻-type semiconductor layer 72 and the metal member 80. The metal member 80 can be formed by through-silicon via (TSV) technology.

For example, one Z-direction end of the metal member 80 is electrically connected to an interconnect 82. The interconnect 82 may be electrically connected to one of the common lines 51. The other end of the metal member 80 is not covered with the p⁺-type semiconductor layer 71. The metal member 80 is electrically isolated from the p⁺-type semiconductor layers 71 and 72 by the insulating layer 81. The potential of the metal member 80 can be set to a different potential from the p⁺-type semiconductor layers 71 and 72.

### Eighth Modification

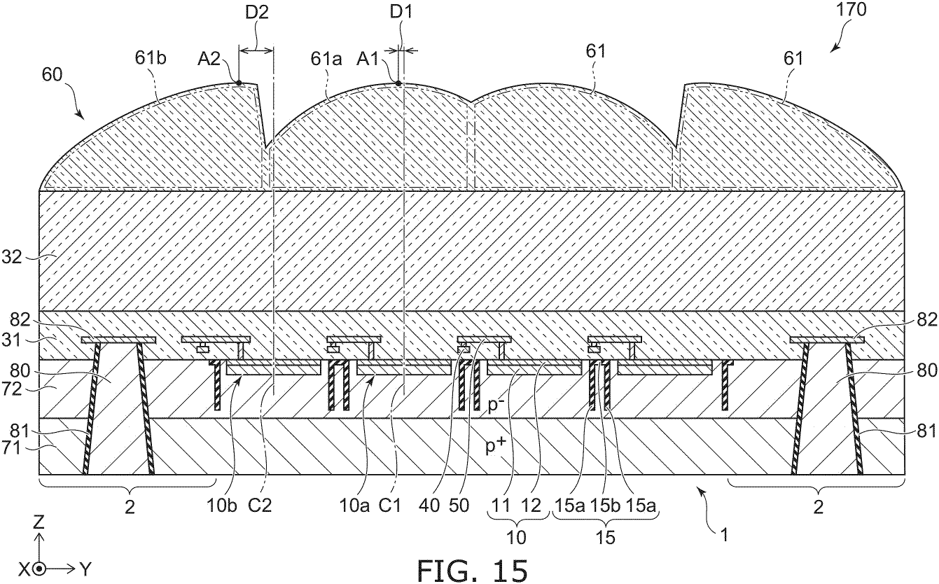

FIG. 16 is a cross-sectional view illustrating a light detector according to an eighth modification of the first embodiment.

In the light detector 180 according to the eighth modification shown in FIG. 16, compared to the light detector 170, at least one second region 2 further includes the n-type semiconductor region 23, the p⁺-type semiconductor region 24, the n⁺-type semiconductor region 25, and the n⁺-type semiconductor region 26. Otherwise, the structure may be similar to that of the light detector 170.

### Ninth Modification

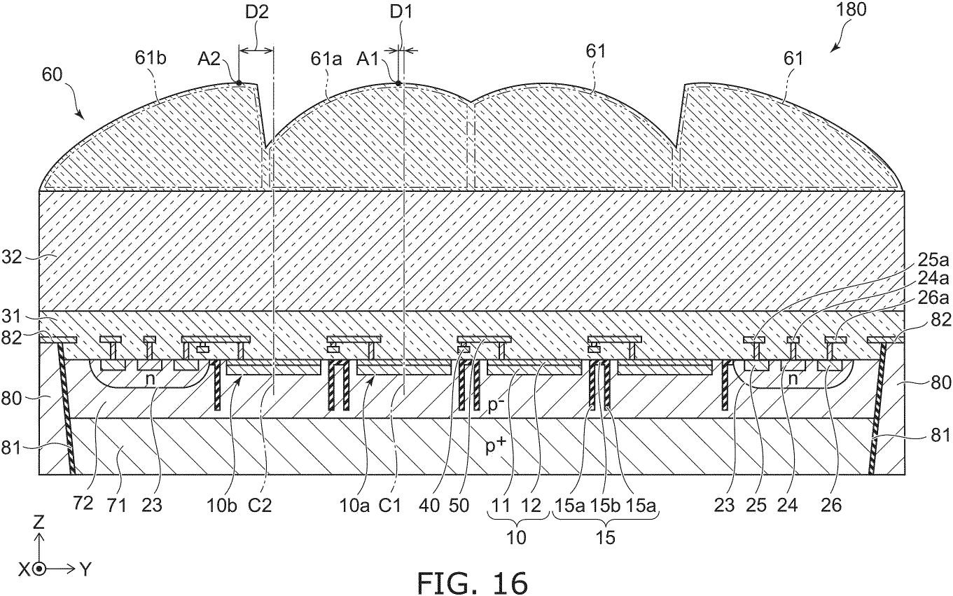

FIG. 17 is a cross-sectional view illustrating a light detector according to a ninth modification of the first embodiment.

Compared to the light detector 100, the light detector 190 according to the ninth modification shown in FIG. 17 further includes a resin layer 90, a first filter layer 91, a second filter layer 92, and a support member 93.

As shown in FIG. 17, the resin layer 90 is positioned on a portion of the second region 2. The resin layer 90 includes a resin that absorbs or reflects light. For example, the n-type semiconductor region 23 overlaps the resin layer 90 when viewed along the Z-direction.

The support member 93 is located on the lens group 60 and the resin layer 90. The support member 93 is light-transmissive. The first filter layer 91 is located on the support member 93. The first filter layer 91 is positioned on the lens group 60 and the resin layer 90. The second filter layer 92 is located between the lens group 60 and the support member 93 and between the resin layer 90 and the support member 93. The thickness in the Z-direction of the support member 93 is greater than the thicknesses in the Z-direction of the resin layer 90, the first filter layer 91, and the second filter layer 92.

The resin layer 90 is provided as an adhesive that bonds the first filter layer 91, the second filter layer 92, and the support member 93 to the insulating layer 32. The resin layer 90 may include a resin that absorbs or reflects light. For example, the resin layer 90 includes an infrared-cutting agent (an IR absorber) that absorbs infrared light. The support member 93 is a glass substrate or a sapphire substrate.

The first filter layer 91 and the second filter layer 92 absorb light of a prescribed range of wavelengths. The materials of the first and second filter layers 91 and 92 can be selected as appropriate according to the wavelength to be absorbed. For example, the first filter layer 91 and the second filter layer 92 include at least one selected from the group consisting of aluminum, silver, gold, magnesium fluoride (MgF₂), lanthanum fluoride (LaF₃), tetrahydrofuran (ThF₃ or ThF₄), silicon oxide (SiO₂), titanium oxide (TiO₂), zirconium oxide (ZrO₂), aluminum oxide (Al₂O₃), magnesium oxide (SiO₂), germanium, and zinc selenide (ZnSe).

For example, the transmittances of the first and second filter layers 91 and 92 for light of a first range of wavelengths is greater than the transmittance for light of a second range of wavelengths. The transmittance of the resin layer 90 for the light of the first range of wavelengths is less than the transmittance for the light of the second range of wavelengths. The light that passes through the first and second filter layers 91 and 92 is absorbed or reflected by the resin layer 90. Thereby, the amount of the light incident on the second region 2 can be effectively reduced. The misoperation of the circuit elements due to the incidence of light on the second region 2 can be suppressed.

For example, the first range is greater than 850 nm and less than 1100 nm. The second range is greater than 400 nm and less than 650 nm. The transmittances of the first and second filter layers 91 and 92 for the light of the first range of wavelengths are greater than 10 times the transmittances for the light of the second range of wavelengths. The transmittance of the resin layer 90 for the light of the second range of wavelengths is greater than 10 times the transmittance for the light of the first range of wavelengths. The transmittances of the first and second filter layers 91 and 92 are not less than 10 times the transmittance of the resin layer 90 for the light of the first range of wavelengths.

In the light detectors 160 to 190 as well, similarly to the light detectors 100 to 150, the lens group 60 is located on the second region 2 in addition to the first region 1. Thereby, the light that is incident on the light detector in a wider area can be detected by the element 10.

The structures according to the modifications described above can be combined as appropriate. For example, one of the light detectors 100 to 150 or 170 to 190 may include an active quenching circuit similar to that of the light detector 160. One of the light detectors 110 to 150 may include the metal member 80 similarly to the light detector 170 or 180. One of the light detectors 110 to 150 may include the resin layer 90, the first filter layer 91, the second filter layer 92, and the support member 93 similarly to the light detector 190.

### Second Embodiment

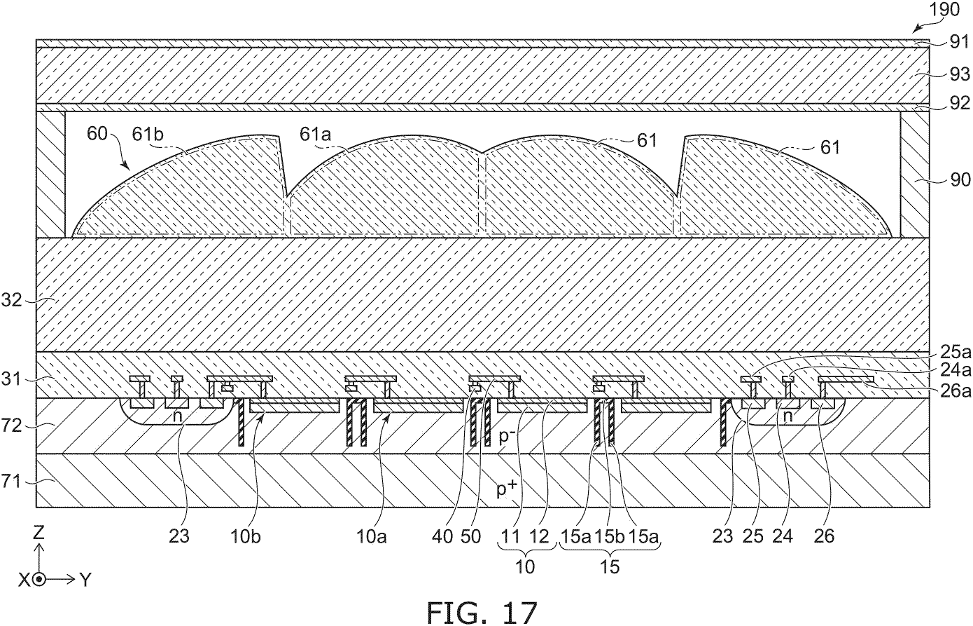

FIG. 18 is a schematic view illustrating a lidar (Laser Imaging Detection and Ranging (LIDAR)) device according to a second embodiment.

The embodiment is applicable to a long-distance subject detection system (LIDAR) or the like including a line light source and a lens. The lidar device 5001 includes a light-projecting unit T projecting laser light toward an object 411, and a light-receiving unit R (also called a light detection system) receiving the laser light from the object 411, measuring the time of the round trip of the laser light to and from the object 411, and converting the time into a distance.

In the light-projecting unit T, a light source 404 emits light. For example, the light source 404 includes a laser light oscillator and produces laser light. A drive circuit 403 drives the laser light oscillator. An optical system 405 extracts a portion of the laser light as reference light, and irradiates the rest of the laser light on the object 411 via a mirror 406. A mirror controller 402 projects the laser light onto the object 411 by controlling the mirror 406. Herein, “project” means to cause the light to strike.

In the light-receiving unit R, a reference light detector 409 detects the reference light extracted by the optical system 405. A light detector 410 receives the reflected light from the object 411. A distance measuring circuit 408 measures the distance to the object 411 based on the reference light detected by the reference light detector 409 and the reflected light detected by the light detector 410. An image recognition system 407 recognizes the object 411 based on the measurement results of the distance measuring circuit 408.

The lidar device 5001 employs light time-of-flight ranging (Time of Flight) in which the time of the round trip of the laser light to and from the object 411 is measured and converted into a distance. The lidar device 5001 is applied to an automotive drive-assist system, remote sensing, etc. Good sensitivity is obtained particularly in the near-infrared region when the light detectors of the embodiments described above are used as the light detector 410. Therefore, the lidar device 5001 is applicable to a light source of a wavelength band that is invisible to humans. For example, the lidar device 5001 can be used for obstacle detection for a mobile body.

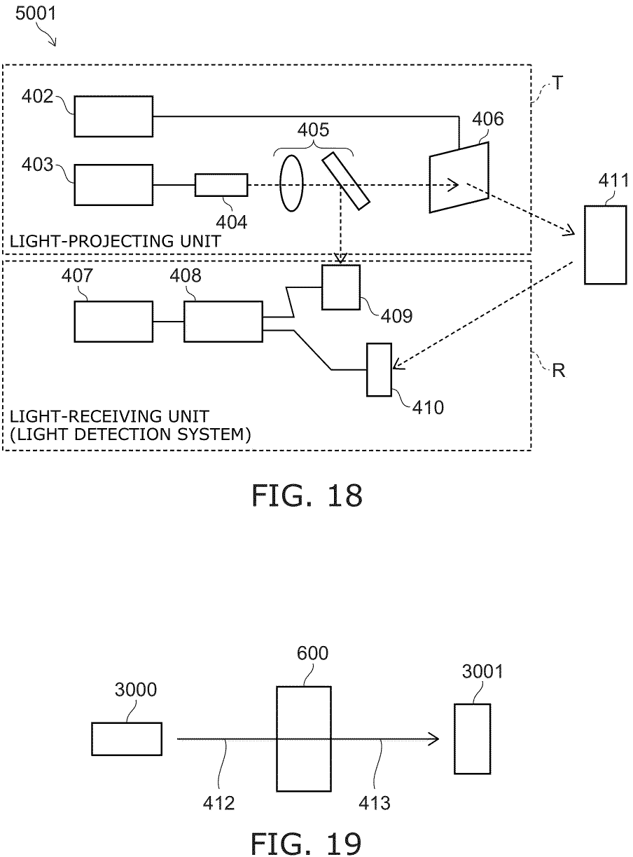

FIG. 19 describes the detection of the detection object of the lidar device.

A light source 3000 emits light 412 toward an object 600 that is the detection object. A light detector 3001 detects light 413 that passes through the object 600, is reflected by the object 600, or is diffused by the object 600.

For example, the light detector 3001 can realize highly-sensitive detection when the light detector according to the embodiment described above is used. It is favorable to provide multiple sets of the light detectors 410 and the light source 404 and to preset the arrangement relationship of the sets in the software (which is replaceable with a circuit). For example, it is favorable for the arrangement relationship of the sets of the light detector 410 and the light source 404 to be provided at uniform spacing. Thereby, an accurate three-dimensional image can be generated by the output signals of each light detector 410 complementing each other.

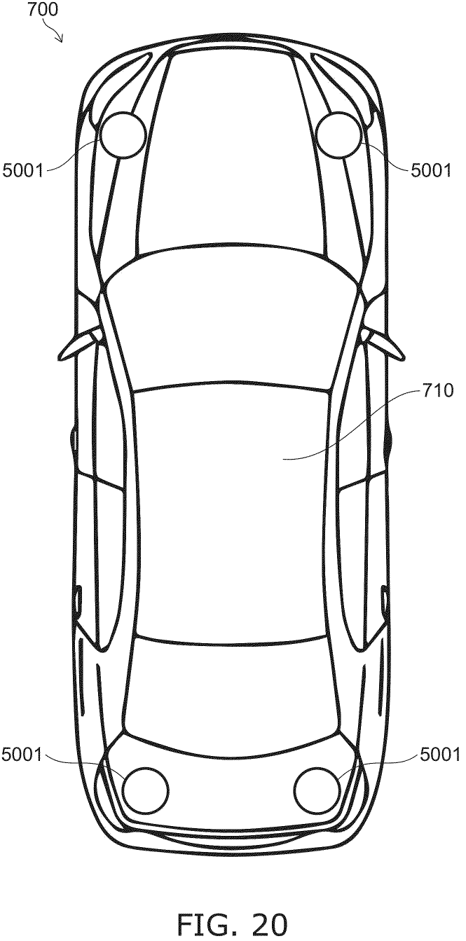

FIG. 20 is a schematic top view of a mobile body including the lidar device according to the second embodiment.

In the example of FIG. 20, the mobile body is a vehicle. A vehicle 700 according to the embodiment includes the lidar devices 5001 at four corners of a vehicle body 710. Because the vehicle according to the embodiment includes the lidar devices at the four corners of the vehicle body, the environment in all directions of the vehicle can be detected by the lidar devices.

Other than the vehicle illustrated in FIG. 20, the mobile body may be a drone, a robot, etc. The robot is, for example, an automatic guided vehicle (AGV). By including the lidar devices at the four corners of such mobile bodies, the environment in all directions of the mobile body can be detected by the lidar devices.

According to embodiments described above, the light detection efficiency of the light detector can be increased.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in light detectors such as elements, semiconductor regions, insulating parts, interconnects, contact plugs, lenses, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all light detectors, light detection systems, lidar devices, and mobile bodies practicable by an appropriate design modification by one skilled in the art based on the light detectors, the light detection systems, the lidar devices, and the mobile bodies described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light detector, comprising:
a first region including a plurality of elements arranged along a first direction and a second direction, the first direction and the second direction crossing each other, each of the plurality of elements including
a first semiconductor region of a first conductivity type, and
a second semiconductor region located on the first semiconductor region, the second semiconductor region being of a second conductivity type;
a second region adjacent to the first region in the second direction, the second region having a different structure from the first region; and
a lens group positioned on the first and second regions,
the lens group including a plurality of lenses located to correspond respectively to the plurality of elements,
the first region, the second region, and the lens group being repeatedly provided in the second direction.

2. The light detector according to claim 1, wherein
a length in the second direction of the lens group is greater than a length in the second direction of the first region.

3. The light detector according to claim 1, wherein
in one of a plurality of the lens groups, the plurality of lenses is linked to each other, and shapes of adjacent lenses of the plurality of lenses are different from each other.

4. The light detector according to claim 1, wherein
in one of a plurality of the lens groups, a shape of the plurality of lenses is symmetric in the second direction.

5. The light detector according to claim 1, wherein
in one of a plurality of the lens groups, a shape of at least one of the plurality of lenses is asymmetric in the second direction.

6. The light detector according to claim 1, wherein
in one of a plurality of the first regions, the plurality of elements includes a first element and a second element,
the second element is adjacent to the first element,
in one of a plurality of the lens groups, the plurality of lenses includes:
a first lens located to correspond to the first element; and
a second lens located to correspond to the second element, and
a distance in the second direction between a center of the first element and an apex of the first lens is greater than a distance in the second direction between a center of the second element and an apex of the second lens.

7. The light detector according to claim 6, wherein
a portion of the first lens is positioned on the second element, and
at least a portion of the second lens is positioned on one of a plurality of the second regions adjacent to the one of the plurality of first regions.

8. The light detector according to claim 6, wherein
a length in the second direction of the second lens is greater than a length in the second direction of the first lens.

9. The light detector according to claim 1, wherein
in one of a plurality of the first regions, the plurality of elements include a first element,
in one of a plurality of the lens groups, the plurality of lenses include a first lens provided corresponding to the first element, and
an apex of the first lens is aligned with a center of the first element in the second direction.

10. The light detector according to claim 1, further comprising:
a first semiconductor layer of the first conductivity type; and
a second semiconductor layer located on the first semiconductor layer,
the second semiconductor layer being of the first conductivity type,
a first-conductivity-type impurity concentration in the second semiconductor layer being less than a first-conductivity-type impurity concentration in the first semiconductor layer,
a plurality of the first regions being located on the second semiconductor layer.

11. The light detector according to claim 1, wherein
each of a plurality of the second regions includes:
a third semiconductor region of the second conductivity type; and
a fourth semiconductor region located on the third semiconductor region, the fourth semiconductor region being of the first conductivity type.

12. The light detector according to claim 10, wherein
the second region includes a metal member and an insulating layer,
the metal member is surrounded with the first and second semiconductor layers in the first and second directions, and
the insulating layer is located between the first semiconductor layer and the metal member and between the second semiconductor layer and the metal member.

13. The light detector according to claim 1, further comprising:
a quenching part electrically connected to at least one of the plurality of second semiconductor regions.

14. The light detector according to claim 13, wherein
the quenching part includes an active quenching circuit, and
at least a portion of the active quenching circuit is located in one of a plurality of the second regions.

15. The light detector according to claim 1, wherein
a surface area of an upper surface of the plurality of lenses included in one of a plurality of the lens groups is greater than 1.05 times and less than 4 times the square of a pitch in the second direction of the plurality of elements included in one of a plurality of the first regions.

16. The light detector according to claim 1, wherein
the first region, the second region, and the lens group also are repeatedly provided in the first direction.

17. The light detector according to claim 1, wherein
one of a plurality of the first regions includes an insulating part located around the plurality of elements in the first and second directions.

18. The light detector according to claim 1, wherein
one of the plurality of elements includes an avalanche photodiode.

19. The light detector according to claim 18, wherein the avalanche photodiode operates in a Geiger mode.

20. A light detection system, comprising:
the light detector according to claim 1; and
a distance measuring circuit calculating a time-of-flight of light by using an output signal of the light detector.

21. A lidar device, comprising:
a light source irradiating light on an object; and
the light detection system according to claim 20 detecting light reflected by the object.

22. The lidar device according to claim 21, further comprising:
an image recognition system generating a three-dimensional image based on an arrangement relationship of the light source and the light detector.

23. A mobile body, comprising:
the lidar device according to claim 21.
